(19) United States
(12) Patent Application Publication
(10) Pub. No.: US 2013/0031928 A1
(43) Pub. Date: Feb. 7, 2013

(54) WIND DIRECTION CONTROLLER FOR CONTROLLING COOLING AIR INSIDE DATA CENTER

(71) Applicant: Jung Ki Kim, Seoul (KR)

(72) Inventor: Jung Ki Kim, Seoul (KR)

(21) Appl. No.: 13/641,118

(22) PCT Filed: Aug. 11, 2011
(86) PCT No.: PCT/KR2011/005885

§ 371 Date: Oct. 14, 2012

(30) Foreign Application Priority Data
Aug. 13, 2010 (KR) 10-2010-0078210

(51) Int. Cl. H05K 7/20; F24F 13/08; F25D 17/04

(52) U.S. Cl. 62/408; 62/259.2; 454/329

(57) ABSTRACT

The present invention provides a wind direction adjuster for controlling cooling air in a data center. The adjuster includes: an access floor-flat plate; a first support, a second support, a third support, and a fourth support that form frames supporting the access floor-flat plate from below; and a wind direction-adjusting plate for concentrating a wind direction of cooling air supplied from an air conditioner by blocking an open space between at least any two supports of the first to fourth supports in accordance with a structure of a building, an installation environment of a computing equipment, and a reach distance of the cooling air.

### BACKGROUND OF THE INVENTION

1. Field of the Invention

The present invention relates to a wind direction adjuster for controlling cooling air in a data center, particularly a wind direction adjuster for controlling cooling air in a data center that can maintain an indoor temperature at a uniform constant temperature and maintain the optimal temperature by controlling the flow of conditioned-air without using any electrical device in a closed space, and can considerably reduce energy that is consumed to operating a cooling apparatus.

2. Description of the Related Art

Data centers such as various types of computer room, communication room, and control room are constructed in institutions such as government bodies, military installations, schools, companies, and institutes, and important systems in the data centers keep operated for 24 hours without stopping.

Various efforts are made to stably operate the systems of the data center installed in the institutions, but the cost for maintaining an appropriate temperature gradually increases due to the machinery that is continuously added.

Further, a large amount of consumed power for operating the data centers is a burden and a countermeasure for reducing has been taken to reduce cost.

An under floor air conditioning system using an access floor or a ceiling air conditioning system with a duct in the ceiling of the data center for cooling has been used to cool the data centers that are generally operated, the cooling system using an access floor is used at present in most data centers. Therefore, the present invention has been made to find out and solve the problems of the under floor air conditioning system.

FIG. 1 is an exemplary view illustrating a structure that is used for common data centers and performs cooling by using an under floor air conditioning system that blows air into the space under the access floor from the sides and blows out the cold air onto the access floor.

FIG. 1 shows an experimental example that the inventor(s) of the application obtained by measuring the installation state of air conditioners, the arrangement positions of computing equipment and a communication rack, and a blown-out wind speed and a real temperature of reserve spaces and a idle space, in person in a data center.

As shown in FIG. 1, for common data centers, air conditioners 10, 10a-10m are installed in data center 100 to cool the computing equipment 20 equipped with a communication rack. As show in the figure, access floor-perforated plates 30 and 32 are disposed around, ahead of and behind or at the left and right of, the computing equipment 20 equipped with a communication rack, for cooling by using cold air blown from the air conditioners 10, 10a-10m.

As shown in the regent in the figure, a high-temperature areas 40 where the computing equipment 20 equipped with a communication rack is installed in close formation and machinery discharges a large amount of heat are installed, reserve spaces 50 where computing equipment equipped with a communication rack will be further installed, dead-cooling areas 55 where the cold air blown out from the air conditioners cannot normally reaches, and an idle space 60 where it is difficult to install machinery, along the edge in the data center 100 are defined in the data center 100. The reference numeral 53 refers to a dead-cooling areas 53.

The inventor(s) of the application measured the wind speeds and temperatures of the parts in the data center 100 having this configuration and the data is shown in the figure.

Referring to the figure, the temperatures of the high-temperature areas 40 where the computing equipment 20 equipped with a communication rack is installed in close formation and machinery discharges a large amount of heat are installed were measured at 23.5° C., 23.8° C., and 23.8° C., the temperatures of the areas where the access floor-perforated plates 30 and 32 with a small amount of discharged heat were measured at 22.0° C., 22.2° C., and 22.9° C., and the temperatures of the dead-cooling areas 55 were measured at 24.0° C., 24.0° C., and 24.3° C.

Consequently, it was found that the temperature measured at the high-temperature areas 40 was 23.7° C. on the average and the temperature measured at the dead-cooling areas 55 was 23.7° C. on the average, and the blown-out wind speeds were measured at 1.2 m/s, 1.3 m/s, and 1.5 m/s.

Accordingly, large temperature differences were generated even in the data center 100 in accordance with the measuring positions.

It becomes necessary for the data center described above to develop a data center cooling structure that can save energy in addition to maintaining the optimum temperature by remarkably improving method and structure of managing the temperature in the data center, as a part of green IT, and there are the following additional problems.

First, there is a problem in that the interior temperature is increasing due to continuous addition of machinery and costly air conditioners are added to cope with the increase of the internal temperature, so that it takes a large cost to operate the equipment in the data center in order to maintain an appropriate temperature.

Second, there is always a problem in the site in that an improvement is taken for smooth circulation of the conditioned-air in the room by installing partitions, flexible ducts, and perforated-plates with a cooling fan, but there is a limit and large difficulty in reducing the interior temperature.

Third, the amount of discharge heat is increased by introducing high-performance and high-density machinery and the temperature around is also increased, which may cause malfunction of the other machine disposed around, and the internal temperature rapidly increases when the air conditioner breaks, so that there is a problem in that an emergency that it is necessary to forcibly stop the machinery that is in normal operation is generated.

Further, it is both realistic difficulty and problem to have to install many pieces of machinery in a small space to reduce the cost, even though there are the problems described above.

Further, there is another problem in that as the conditioned-air from the air conditioners is supplied even to the reserve spaces and the idle space, energy is lost and it is difficult to intensively supply the conditioned-air to the area where the computing equipment with a communication rack is installed. This is also a cause that deteriorates cooling efficiency.

Further, some of the air conditioners are overloaded by an increase in temperature at specific areas, which causes the lifespan of the machinery to be reduced and the generation rate of a defect of the parts in the machinery to be increased.

### SUMMARY OF THE INVENTION

The present invention has been made in an effort to provide a wind direction adjuster for controlling cooling air in a data center that precludes energy loss and cooling loss by preventing cooling air from being supplied to an area without discharged heat or with a small amount of discharged heat and by preventing conditioned-air to be supplied to a reserve space and an idle space that are not necessary to be supplied with cooling air, by configuring a wind direction adjuster that controls the flow of conditioned-air discharged from a side exit under an access floor in consideration of the structure and area of a building, the arrangement of machinery, the amount of discharged heat, and air conditioners.

Further, the present invention provides a wind direction adjuster for controlling cooling air in a data center that increases energy efficiency and maximizes a cooling effect by intensively supplying conditioned-air to a space where computing equipment with a communication rack is installed.

Further, the present invention provides a wind direction adjuster for controlling cooling air in a data center that uniformly supplies conditioned-air to a section where machinery is installed, even if some air conditioners stop.

An exemplary embodiment of the present invention provides an access floor support-type of wind direction adjuster 200 for controlling cooling air in a data center, which is a wind direction adjuster for controlling cooling air in a data center and includes: an access floor-flat plate 110; a first support 111, a second support 112, a third support 113, and a fourth support 114 that form frames supporting the access floor-flat plate from below; and a wind direction-adjusting plate 120 that concentrates the wind direction of cooling air supplied from an air conditioner by blocking an open space between at least any two supports of the first to fourth supports in accordance with the structure of a building, the installation environment of computing equipment, and the reach distance of the cooling air.

The wind direction-adjusting plate 120 may be fixed to any two supports of the first to fourth supports by fixing devices and adjust a wind direction and may be attachable/detachable by Velcro tapes that are easily attachable/detachable, and the wind direction adjuster may further include first to fourth bottom support members 111a, 112a, 113a, and 114a that fix and support the first to fourth supports to a floor.

The access floor-flat plate may be any one of a flat plate or a flat plate with holes by boring.

Another exemplary embodiment of the present invention provides a wind direction-variable type of wind direction adjuster 300 for controlling cooling air in a data center includes: an access floor-flat plate 110; a wind direction variator 130 that is installed at the center on the underside of the access floor-flat plate to adjust a wind direction to be variable; a wind direction-adjusting plate 120a that is installed on the underside of the wind direction variator 130 and adjusts the wind direction by integrally rotating integrally; a first support 111 that is a support bar supporting the wind direction-adjusting plate 120a to a floor; and a first support member 111a that allows the bottom of the first support 111 to be seated and fixed to the floor.

The wind direction-adjusting plate 120a and the wind direction variator 130 may be directly connected, with the access floor-flat plate 110 therebetween, and the direction of the wind direction-adjusting plate 120a may be changed by rotating the wind direction variator 130 to the left or right.

The wind adjuster for controlling cooling air in a data center according to an exemplary embodiment of the present invention has a remarkable effect that preclude energy loss and cooling loss by preventing conditioned-air from being supplied to a reserve space and an idle space that do not need to be supplied with cooling air.

Further, the configuration of the present invention achieves an effect that increases energy efficiency and maximizes a cooling effect by intensively supplying conditioned-air to a space where computing equipment equipped with a communication rack is installed.

Further, according to an exemplary embodiment of the present invention, it is also possible to achieve an effect that can uniformly supply conditioned-air to a section where machinery is installed, even if some air conditioners stop.

### BRIEF DESCRIPTION OF THE DRAWINGS

FIG. 1 is an exemplary view illustrating a structure that is used for common data centers and performs cooling by using an under floor air conditioning system that blows air into the space under the access floor from the sides and takes out the cold air onto the access floor.

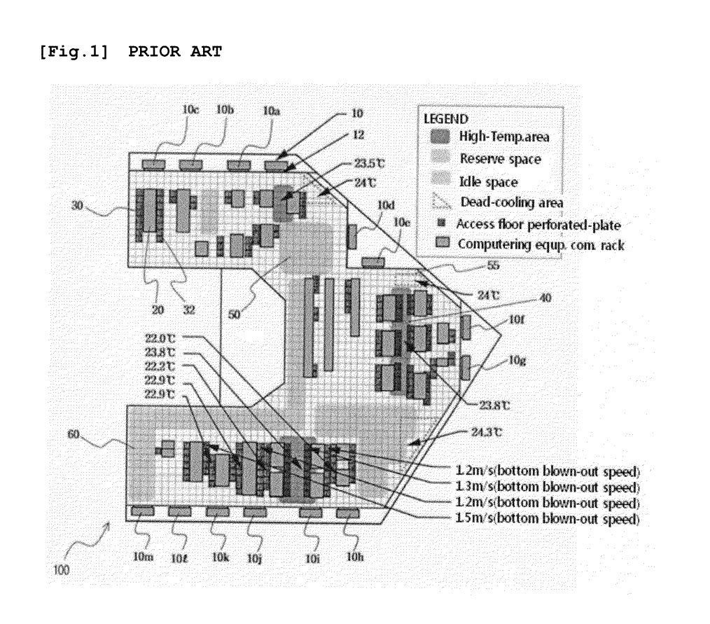

FIGS. 2 and 3 are configuration views showing an access floor support-attached type of wind direction adjuster with a wind direction-adjusting plate, which can adjust a wind direction, attached to the underside of an access floor, according to a first exemplary embodiment of the present invention.

FIGS. 4 and 5 are views illustrating the wind direction adjustment principle of the access floor support-attached type of wind direction adjuster for controlling cooing air under an access floor in a data center, according to the first exemplary embodiment of the present invention.

FIGS. 6 and 7 are configuration views showing an access floor wind direction-variable type of wind direction adjuster equipped with a wind direction variator, which can change a wind direction, on an access floor, and a wind direction-adjusting plate under the wind direction variator, according to a second exemplary embodiment of the present invention.

FIGS. 8 and 9 are views illustrating the wind direction adjustment principle of the access floor wind direction-variable type of wind direction adjuster for controlling cooing air under an access floor in a data center, according to the second exemplary embodiment of the present invention.

FIG. 10 is a configuration view illustrating data of a measured temperature and a measured wind speed, when the access floor support-attached type of wind direction adjuster, which is equipped with the wind direction-adjusting plate according to an exemplary embodiment of the present invention, is attached.

### DETAILED DESCRIPTION OF THE PREFERRED EMBODIMENTS

Hereinafter, exemplary embodiments of the present invention will be described in detail with reference to the accompanying drawings.

### First Exemplary Embodiment

### (Structure)

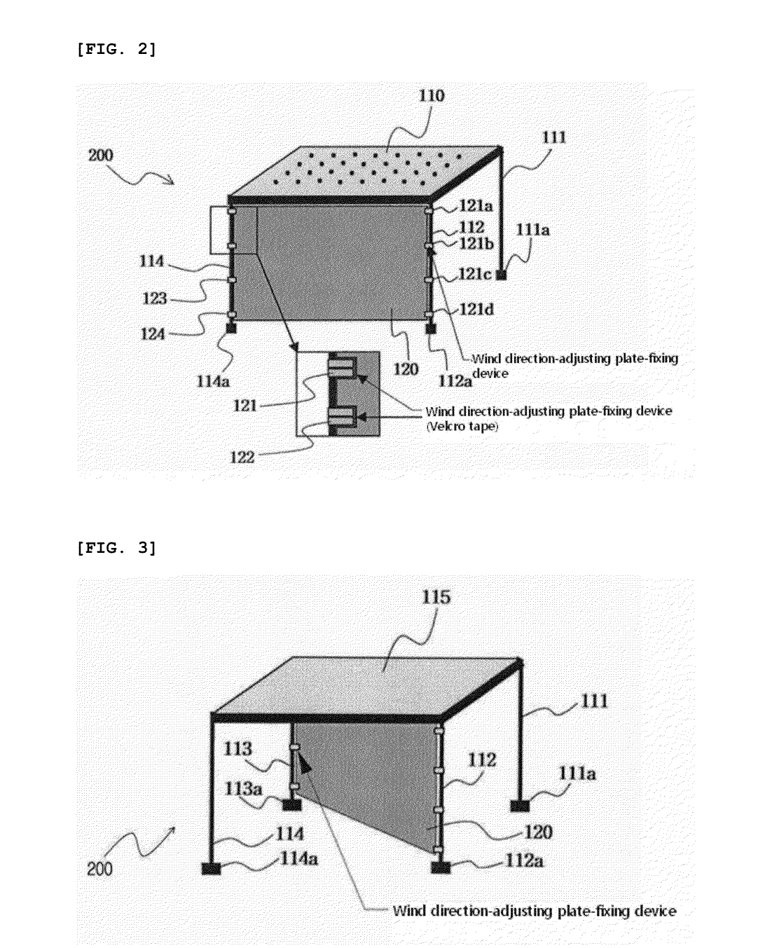

FIGS. 2 and 3 are configuration views showing an access floor support-attached type of wind direction adjuster that is equipped with a wind direction control board, which can adjust a wind direction, on the underside an access floor, according to a first exemplary embodiment of the present invention. FIG. 2 shows an example of using an access floor-perforated plate formed by boring the topside of an access floor and FIG. 3 is an example of using an access floor configured by a flat plate.

Referring to the figures, a wind direction adjuster for controlling cooling air under an access floor in a data center according to an exemplary embodiment of the present invention, includes: an access floor-flat plate 110; a first support 111, a second support 112, a third support 113, and a fourth support 114 that are frames supporting the access floor-flat plate from below; a wind direction-adjusting plate 120 that can concentrate the wind direction of cooling air supplied from an air conditioner by blocking an open space between at least any two supports of the first to fourth supports; and first to fourth bottom support members 111a, 112a, 113a, and 114a that support the bottoms of the first to fourth supports.

According to this structure, it is possible to intensively supply conditioned-air supplied from an air conditioner, so that it is possible to more effectively achieve a cooling effect even without adding a specific cooling system, by installing a wind direction adjuster 200 for controlling cooling air under an access floor according to the configuration according to an exemplary embodiment of the present invention at an area where computing equipment 20 equipped with a communication rack is installed. The detailed operation principle will be described below.

Further, in an exemplary embodiment of the present invention, the wind direction-adjusting plate 120 is fixed to any two supports of the first to fourth supports by fixing devices and adjusts a wind direction and is attachable/detachable by Velcro tapes 121, 122, 123, 124 and 121a, 122b, 123c, 124d that are easily attachable/detachable.

In FIG. 2, the wind direction-adjusting plate 120 is installed between the second support 112 and the fourth support 114 and fixed by attaching the Velcro tapes 122, 123, 124 and 121a, 122b, 123c, 124d that are attachable/detachable by both sides.

Further, in FIG. 3, the wind direction-adjusting plate 120 is installed between the second support 112 and the third support 113 and fixed by attaching the Velcro tapes 122, 123, 124 and 121a, 122b, 123c, 124d that are attachable/detachable by both sides.

In the structure shown in FIG. 2, the access floor disposed at the upper portion is bored and the wind direction can be concentrated forward or rearward, and in the structure shown in FIG. 3, the access floor disposed at the upper portion is a flat plate without being bored and conditioned-air can be diagonally and intensively supplied.

This is for illustrating an example that allows a user to simply adjust the wind direction while measuring a temperature change in a site.

Further, although the Velcro tapes 121, 122, 123, 124 and 121a, 122b, 123c, 124d that are easily attachable/detachable are used to fix the wind direction-adjusting plate 120, it should be understood that there is no problem even in using products composed of bolts and nuts or ropes, which are common fasteners.

As described above, the access floor support-attached type of wind direction adjuster according to the first exemplary embodiment may be mainly installed at an area where machinery such as computing equipment 20 equipped with a communication rack and a server is installed in close formation and machinery discharging a large amount of heat is installed. The wind direction-adjusting plate 120 is installed under the access floor around the area, where machinery is installed such that conditioned-air can be intensively supplied to the area, to be able to control the flow of conditioned-air, for partitioning, thereby functioning to guide air.

Further, as the access floor support-attached type of wind direction adjuster is installed, there is an effect that energy loss and cooling loss are prevented by preventing conditioned-air from being supplied to an area where machinery, which does not discharge heat or discharges a small amount of heat, is installed, an idle space, or a reserve space.

It is important in the detailed constructing and manufacturing processes to use a fire-retardant material having small deformation for manufacturing the wind direction-adjusting plate 120 and to allow the wind direction-adjusting plate 120 to be fixed to the access floor supports. Attachment/detachment is made easy by using Velcro tapes in an exemplary embodiment of the present invention. Further, the wind direction-adjusting plate can be adjusted in height in accordance with the installation area and the environment and can be installed by being simply attached to even to the sides of the supports or in the diagonal direction.

### First Exemplary Embodiment: Principle of Adjusting Wind Direction

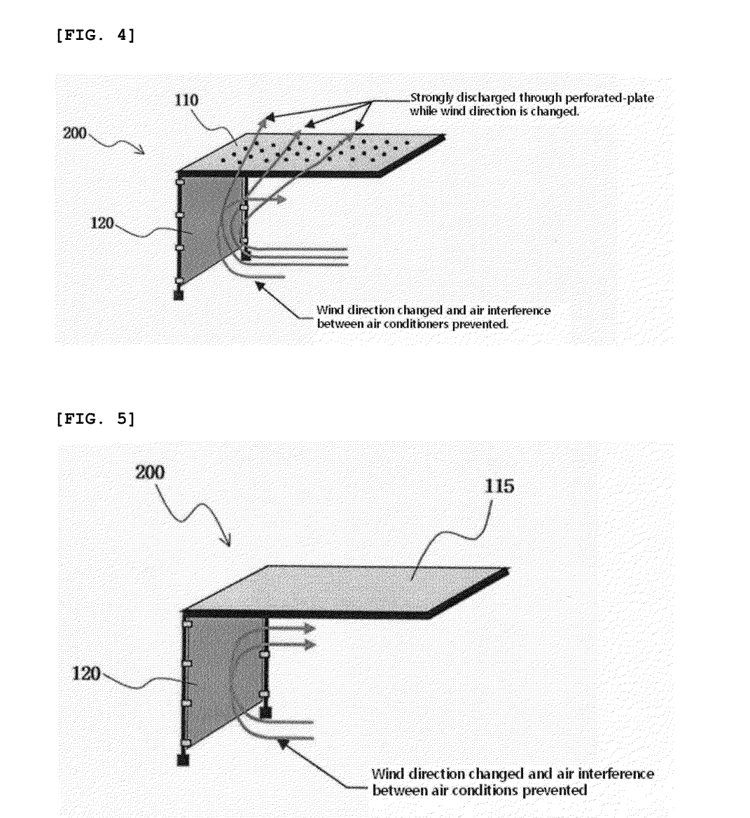

FIGS. 4 and 5 are views illustrating the wind direction adjustment principle of the wind direction adjuster for controlling cooing air under an access floor in a data center, according to the first exemplary embodiment of the present invention.

As shown in the figures, the access floor support-attached type of wind direction adjuster 200 according to an exemplary embodiment of the present invention is achieved by attaching the wind direction-adjusting plate 120 to the underside of access floor plates (or perforated-plates) 110 and 115 disposed at the upper portion, between the third support 113 and the fourth support 114.

In this structures, as an air conditioner supplies conditioned-air, the supplied conditioned-air turns while hitting the wind direction-adjusting plate 120, so that the cooling air is blown out through the access floor perforated-plate at the upper portion or refracted by hitting the flat plate 110.

It can be seen from the figures that the wind direction-adjusting plate 120 functions to change the wind direction and prevent spatial interference between air conditioners, and then the perforated-plate is disposed at the upper portion, the wind direction changes while the air passing through the holes, so that the air is strongly blown out through the perforated-plate. It is possible to increase a cooling effect by arranging the computing equipment 20 equipped with a communication rack and a server on the access floor in consideration of this fact.

### Second Exemplary Embodiment

### (Structure)

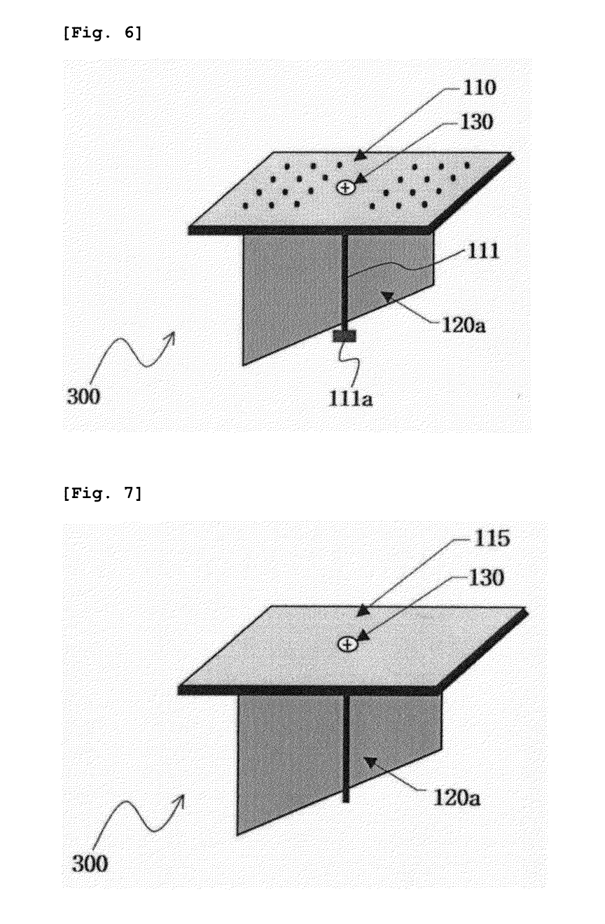

FIGS. 6 and 7 are configuration views showing an access floor wind direction-variable type of wind direction adjuster equipped with a wind direction variator, which can change a wind direction, on an access floor, and a wind direction-adjusting plate under the wind direction variator, according to a second exemplary embodiment of the present invention. FIG. 6 shows an example of using an access floor-perforated plate formed by punching the topside of an access floor and FIG. 7 is an example of using an access floor configured by a flat plate.

Referring to the figures, a wind direction-variable type of wind direction adjuster 300 for controlling cooling air under an access floor in a data center according to an exemplary embodiment of the present invention, include: an access floor-flat plate 110; a wind direction variator 130 that is installed at the center on the underside of the access floor-flat plate to adjust a wind direction to be variable; a wind direction-adjusting plate 120a that adjusts the wind direction by rotating integrally with the wind direction variator 130; a first support that is a support bar supporting the wind direction-adjusting plate 120a; and a first support member 111a that allows the bottom of the first support 111 to be seated on a floor.

According to this structure, it is possible to change the direction of conditioned-air supplied from an air conditioner, above the access floor, and to selectively supply the conditioned-air, so that it is possible to achieve an effect that can improve a cooling effect in a desired direction of a user even without adding a specific cooling system, by installing the wind direction-variable type of wind direction adjuster 300 according to the configuration of the present invention at an area where computing equipment 20 equipped with a communication rack and a server are installed. The detailed operation principle will be described below.

According to the wind direction-variable type of wind direction adjuster 300 according to the second exemplary embodiment of the present invention, it is possible to guide conditioned-air, by adjusting the wind direction with a simple structure, to an area with a large amount of discharged heat or an area where the temperature is high when malfunction is generated in some air conditioners, in the section where the support-attached type of wind direction adjuster described in the first exemplary embodiment is installed, so that the wind direction-variable type of wind direction adjuster 300 may be used together with that of the first exemplary embodiment to supplement each other.

The feature is that a user can adjust the wind direction of the conditioned-air in a desired direction and notable points in construction are as follows.

The wind direction-adjusting plate 120a of the wind direction-variable type of wind direction adjuster 300 according to the second exemplary embodiment is made of a firm and fire-retardant material such that the height is freely adjusted. Further, the wind direction-adjusting plate 120a is provided with a fixing device to be easily attached to the wind direction variator 130 disposed on the access floor-flat plate 110 and a device that can fix the end of the wind direction-adjusting plate to the access floor.

Further, the wind direction variator 130 should be firmly fixed to the access floor-flat plate 110 and be manufactured without prominence and depression on the surface.

As shown in FIGS. 6 and 7, the access floor-flat plate 110 may be configured by a flat plate 115, which may be bored or not.

The wind direction-variable type of wind direction adjuster 300 having the configuration according to the second exemplary embodiment of the present invention allows a user to simply adjust a direction with a driver or the like, above the wind direction-variable type of wind direction adjuster 300, for use.

### Second Exemplary Embodiment: Principle of Adjusting Wind Direction

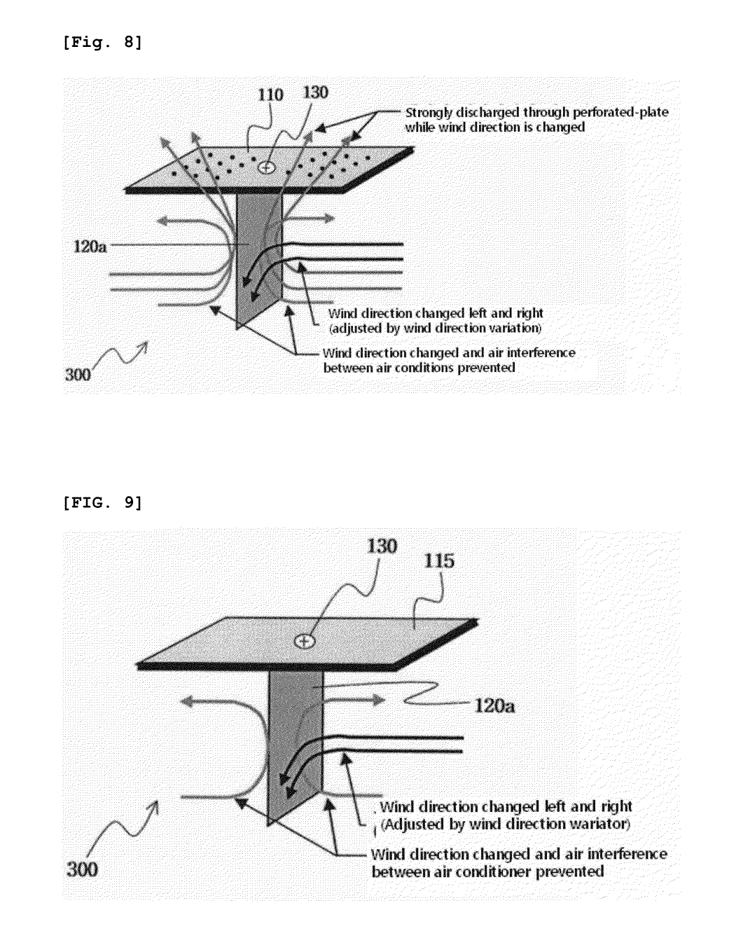

FIGS. 8 and 9 are views illustrating the wind direction control principle of the access floor wind direction-variable type of wind direction adjuster for controlling cooing air in a data center, according to the second exemplary embodiment of the present invention.

As shown in the figures, the access floor support wind direction-variable type of wind direction adjuster 300 according to an exemplary embodiment of the present invention is achieved by disposing the wind direction variator 130 on the access floor-flat plates (or perforated-plates) 110 and 115 disposed at the upper portion, and attaching the wind direction-adjusting plate 120a to the underside of the wind direction variator 130 to operate with each other.

A user can set and then fix a direction such that conditioned-air can be intensively supplied to an area where computing equipment 20 equipped with a communication rack and a server are installed in close formation or a corresponding section when there is a problem due to breakdown of an air conditioner.

Referring to FIG. 8, the conditioned-air is reflected from the wind direction-adjusting plate 120a, so that the supplied direction is adjusted left and right. In detail, it is possible to concentrate the wind direction to the section that needs to be reduced in temperature, by adjusting the wind direction variator 130 disposed at the upper portion.

It can be seen from the figures that the wind direction-adjusting plate 120a functions to change the wind direction and prevent spatial interference between air conditioners, and then the perforated-plate is disposed at the upper portion, the wind direction changes while the air passing through the holes, so that the air is strongly blown out through the perforated-plate. It is possible to increase a cooling effect by arranging the computing equipment 20 equipped with a communication rack and a server on the access floor in consideration of this fact.

Referring to FIG. 9, the access floor disposed at the upper portion is not bored, in which it is possible to achieve an effect that it is possible to concentrate the wind direction to a necessary section by changing the wind direction to the left and right. According to this configuration, it is also possible to prevent air interference between air conditioners, so that it is possible to effectively manage energy.

According to the configuration, it is possible to provide a wind direction adjuster for controlling conditioned-air in a data center which makes it possible to uniformly supply conditioned-air to a section where machinery is installed, from cooling air even if some air conditioners stop.

In this configuration, the conditioned-air discharged from an air conditioner horizontally spreads in the space under the access floor and the flow of the conditioned-air can be adjusted by using the wind direction adjuster in consideration of the reach distance and the influenced area of the conditioned-air. In detail, it is possible to adjust the amount of conditioned-air blown out through the access floor-perforated plate, the flow of air is guided by adjusting the direction of the conditioned-air to function as a partition, and interference of air between air conditioners, so that a cooling efficiency can be increased.

Next, an economic effect and a cooling effect are compared and analyzed by explaining an example of installing the wind direction adjuster for controlling cooing air in a data center according to an exemplary embodiment of the present invention and a site test result.

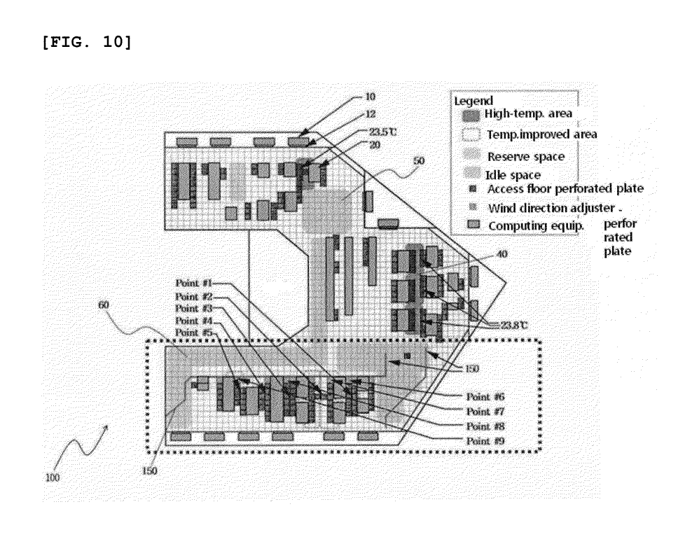

FIG. 10 is a configuration view illustrating data of a measured temperature and a measured wind speed, when the access floor support-attached type of wind direction adjuster according to the first exemplary embodiment of the present invention, is installed. In the figure, a reference numeral ‘150’ indicates a section where the access floor support-attached type of wind direction adjuster according to the first exemplary embodiment of the present invention is installed, which is shown by a blue solid line.

First, the installation specifications of the a wind direction adjuster for controlling cooling air under an access floor in a data center according to an exemplary embodiment of the present invention, depending on the machinery and the environment of the data center, are described.

First, an area with a large amount of discharged heat and an area with a small amount of discharged heat are divided by analyzing the equipment, the cooling type, and the amount of discharged heat in a computer room.

(1) Areas where devices such as a server, a disk device, and communication equipment rack, which discharge a large amount of heat, are disposed.

The access floor support-attached type of wind direction adjuster 200 having the structure described in the first exemplary embodiment is installed in the areas to function as a partition and guide air in order to control the flow of conditioned-air in the space under the access floor such that conditioned-air can be intensively supplied to the area where the machinery is installed, in consideration of the cooling type, density of the installed machinery, and the large amount of discharged heat.

(2) Areas where a printer, a cable rack, a taping device, and a cabined panel rack, which are equipment discharging a relatively small amount of heat, are installed.

Since it is not necessary to intensively supply cooling air to the areas, the access floor support-attached type of wind direction adjuster 200 is installed in the space under the access floor to prevent inflow of conditioned air such that the conditioned-air is guided to the areas where the machinery discharging a large amount of heat is installed.

Second, the access floor support-attached type of wind direction adjuster 200 is installed in a reserve space and an idle space to prevent inflow of conditioned-air, thereby preventing energy loss and minimizing cooling loss.

Third, when malfunction is generated in some air conditioners, the variable-type of wind direction adjuster 300 is installed and the wind direction of the cooling air is adjusted to be used such that the cooling air can be uniformly supplied and spread in the area where the machinery is installed.

### (Result of On-Site Test)

The inventor(s) of the application installed a wind direction adjuster for controlling cooling air in a data center which has the configuration at the work place, tested the result, and achieved the following result.

### 1. First Test

A. Test Environment

Place: Busan Data Center of KRX (Korea Stock Exchange)

Scale 75 pyong (specific section set was set in a computer room where machinery was installed and in operation). 1 pyong corresponds approximately to 36 ft2.

Number of installed air conditioners: six package type of 20RT

B. Test Period

To May 1, 2010 after installing the window direction adjuster on Apr. 16, 2010

C. Test Method

Changes in the following items were checked before and after installing the wind direction adjuster.

(1) Temperature and blown-out speed of conditioned air from access floor were measured

(2) Return temperature of air conditioner was measured

(3) Operation rate of air conditioner was measured

(4) Amount of consumed power was measured

Check point was designated in test set section

(1) Five temperature check pointers (point #1-point #5 in FIG. 10)

(2) Nine blown-out speed check pointers of cooling air from access floor (point #1-point #9)

Check time: 4 p.m. after closing the bell during test period (for 15 days)

Used tool: Digital temperature/moisture/wind speed/illuminance meter (LUTRON LM-8000)

D. Test Result

The on-site test result by the inventor(s) of the application is as the following Table 1.

TABLE 1

| | |
|---|---|
| | Floor air |
| Temperature | blown-out speed |

| | Before | After | Before | After |
|---|---|---|---|---|
| Items | improved | improved | improved | improved |
| Point #1 | 22.0° C. | 20.3° C. | 1.2 m/s | 1.3 m/s |
| Point #2 | 23.8° C. | 22.3° C. | 1.0 m/s | 1.7 m/s |
| Point #3 | 22.2° C. | 20.4° C. | 1.8 m/s | 1.9 m/s |
| Point #4 | 22.9° C. | 21.1° C. | 1.3 m/s | 1.8 m/s |
| Point #5 | 22.9° C. | 21.5° C. | 1.7 m/s | 1.8 m/s |
| Point #6 | — | — | 1.2 m/s | 1.7 m/s |
| Point #7 | — | — | 1.3 m/s | 1.5 m/s |
| Point #8 | — | — | 1.2 m/s | 1.7 m/s |
| Point #9 | — | — | 1.5 m/s | 1.9 m/s |

As shown in the test result in Table 1, the temperature and the blown-out speed of the air from the access floor in the computer room were remarkably improved.

In detail, the temperature of the computer room decreased by 1.7 degrees on the average (−1.7° C. dropped) and the floor air blown-out speed measured around the floor was improved by 0.3 m/s on the average (+0.3 m/s improved).

Further, it was found that the average return temperature of the six air conditioners decreased to 22.43° C., by −0.24° C., from 22.67° C. As described above, it was possible to decrease the temperature in the computer room (data center) even without adding a specific air conditioner.

Next, the result of measuring the temperatures of the computer room (data center) before and after installing the wind direction adjuster for controlling cooling air in a data center according to an exemplary embodiment of the present invention is as the following Table 2.

### [Table 2]

(Unit ° C.)

TABLE 2
(Unit: ° C.)

| | | | Computer room | | | | |
|---|---|---|---|---|---|---|---|
| | Measuring | Measuring | temperature sensor (Check pointer) | | | | |
| Item | Date | Time | Point#1 | Point#2 | Point#3 | Point#4 | Point#5 |
| Before | 4/13 | 16:00 | 22.0 | 23.8 | 22.2 | 22.9 | 22.9 |
| Installing | | | | | | | |
| After | 4/19 | 16:00 | 20.0 | 21.4 | 20.0 | 21.7 | 22.1 |
| Installing | 4/20 | 16:00 | 20.9 | 22.6 | 21.4 | 21.2 | 21.8 |
| | 4/22 | 16:00 | 19.8 | 22.8 | 20.9 | 20.9 | 20.7 |
| | 4/23 | 16:00 | 20.2 | 22.3 | 20.2 | 21.0 | 21.3 |
| | 4/26 | 16:00 | 20.4 | 22.3 | 19.5 | 20.8 | 21.6 |

| | | | | | |
|---|---|---|---|---|---|
| Average | 20.26 | 22.28 | 20.40 | 21.12 | 21.50 |

| | | | | | |
|---|---|---|---|---|---|
| Temp. Difference | −1.74 | −1.52 | −1.80 | −1.78 | −1.40 |
| before/after installing | | | | | |

As shown in Table 2, it can be seen that the average temperature change before and after installing the wind direction adjuster for controlling cooling air in a data center according to an exemplary embodiment of the present invention was −1.7° C.

As described above, as the temperature is uniformly decreased throughout the data center, additional effects that it is possible to extend the lifespan of the equipment by suppressing heat discharged from the machinery in addition to save the power, are expected.

Next, returns temperatures of the air conditioners measured before and after installing the wind direction adjuster for controlling cooling air in a data center according to an exemplary embodiment of the present invention are shown in the following Table 3.

TABLE 3
(Unit: ° C.)

| | Measuring | Measuring | Return Temperatuure of Air Conditioner | | | | | |
|---|---|---|---|---|---|---|---|---|
| Item | Date | Time | 11 | 12 | 13 | 14 | 15 | 16 |
| Before | 4/11 | 16:00 | 22.8 | 23.1 | 23.4 | 22.7 | 21.9 | 22.1 |
| Installing | | | | | | | | |
| After | 4/19 | 16:00 | 22.5 | 23.0 | 22.6 | 22.6 | 21.7 | 21.9 |
| Installing | 4/20 | 16:00 | 22.1 | 23.0 | 22.7 | 22.4 | 21.7 | 21.9 |
| | 4/23 | 16:00 | 22.5 | 23.0 | 22.7 | 22.9 | 22.3 | 22.4 |
| | 4/24 | 16:00 | 22.4 | 23.0 | 22.7 | 22.9 | 21.8 | 22.0 |
| | 4/26 | 16:00 | 22.5 | 22.9 | 22.6 | 22.4 | 21.8 | 22.0 |

| | | | | | | |
|---|---|---|---|---|---|---|
| Average | 22.38 | 22.98 | 22.66 | 22.64 | 21.86 | 22.04 |

| | | | | | | |
|---|---|---|---|---|---|---|
| Temp. difference before/ | −0.42 | −0.12 | −0.74 | −0.06 | −0.04 | −0.06 |
| after installing | | | | | | |

In Table 3, the numbers of air conditioners (11-th to 16-th) indicate the numbers of the air conditioners installed at present in the Busan Data Center of KRX.

As shown in Table 3, it can be seen that the difference in average temperature measured before and installing is −0.24° C.

Next, the energy cost reduced in the first test period that was performed as described above is described.

(1) Average power consumption per day before installing wind direction adjuster (May, 2010)

TABLE 4

| | |
|---|---|
| Reference | |
| meter-reading date | Power (KW) |

| | | |
|---|---|---|
| 10:00 AM, March 1, 2010 | 1,783,824 | |
| 10:00 AM, April 1, 2010 | 1,882,800 | |
| Average power | Formula: | 3,192.77 |
| consumption per day | (1,882,800 − | |
| | 1,783,824)/31(Days) | |

(2) Average power consumption per day after installing wind direction adjuster

TABLE 5

| | |
|---|---|
| Reference | |
| meter-reading date | Power (KW) |

| | | |
|---|---|---|
| 4 PM, April 1, 2010 | 1,931,040 | |
| 4 PM, May 1, 2010 | 1,977,276 | |
| Average power | Formula: | 3,082.4 |
| consumption per day | (1,977,276 − | |
| | 1,931,040)/15(Days) | |

Table 4 and Table 5 show the measured value of the amount of power before and after installing the wind direction adjuster for controlling cooling air in a data center according to an exemplary embodiment of the present invention.

As can be seen from the tables, it was possible to see that the amount of consumed power was remarkably decreased after installing the wind direction adjuster for controlling cooling air in a data center according to an exemplary embodiment of the present invention.

In detail, the details of the reduction of consumed power are as follows. That is, the detail of the reduction of the amount of consumed power per day after installing the wind direction adjuster (for 75 pyong) is A: 3,192.77 [KW]−3,082.4 [KW]=110.37 [KW], and it can be seen that when calculating the details of reduction of consumed power and reduction of cost per day for 1 pyong on the basis of the reduction of the amount of consumed power described above, it is B: 1.47 [KW]*100.9 Won=148 Won(power rate peri kwh, for 100.9 Won). As a result, a considerable economic effect that reduces 148 Won per day for 1 pyong is achieved, as the amount of consumed power per 1 pyong of the data center is reduced.

Further, the yearly reduced cost more increases when the economic reduced cost is applied to the computer rooms of A-dong and B-dong of Anyang Backup Center and the headquarter of KOSCOM, which is shown in the following Table 6.

TABLE 6

| | | Area | | |
|---|---|---|---|---|
| Item | | (pyong) | Reduced cost (year) | Reference |
| the 2nd basememnt of | | 249 | 13,433,420 Won | |
| headquarter | | | | |
| Anyang A-dong | Second | 455 | 24,579,100 Won | |
| | floor | | | |
| | Third | 455 | 24,579,100 Won | |
| | floor | | | |

| | | |
|---|---|---|
| Anyang B-dong | 150 | 8,103,000 Won |
| (Backup computer room) | | |
| Total | 1,309 | 70,704,620 Won |

Referring to Table 6, when the wind direction adjuster for controlling cooling air in a data center according to an exemplary embodiment of the present invention is installed A-dong and B-dong of Anyang Backup Center and the headquarter of KOSCOM, an effect that reduces a large amount of money, 70,704,620 Won, per year is generated, and the machinery is maintained at an appropriate temperature and an effect of increasing the lifespan by preventing overheating is also generated.

Next, the amount of reduced money for power rate that is expected when the wind direction adjuster is applied to the computer rooms of KRX in Seoul and Busan is shown in Table 7.

TABLE 7

| Computer room | Area (pyong) | Reduced cost (year) | Reference |
|---|---|---|---|
| Fourth floor of | 285 | 15,395,700 Won | |
| extension in Seoul | | | |
| Busan (fifth floor | 217 | 11,722,340 Won | |
| of KT IDC) | | | |
| Total | 502 | 27,118,040 Won | |

As shown in Table 7, the amount of reduced money for power rate that is expected when the wind direction adjuster is applied to the computer rooms of KRX in Seoul and Busan is 27,118,040 Won or more per year.

This is the reduced cost calculated when the wind direction adjuster is applied to KRX, but the wind direction adjuster may be applied to the data centers (computer rooms) established throughout the country, so that it is possible to stably operate the machinery and extend the lifespan by cooling the equipment to be safely protected from high-temperature heat, and it is also possible to remarkably contribute to reducing the amount of power.

As described above, the wind direction adjuster for controlling cooling air in a data center having the configuration according to a configuration of the present invention has the advantage that it may be directly applied without changing the existing machinery and equipment at a low cost, has an effect of decreasing the average temperature of the computer rooms by 1.7° C. and an effect of extending the lifespan of the machinery and the parts and removing malfunction factors in advance.

Further, the wind direction adjuster for controlling cooling air in a data center according to a configuration of the present invention can be easily moved and has a reusable structure, so that it can be semipermanently used.

### Secondary Test (Period: May 1 to Jun. 1, 2010)

The inventor(s) of the application additionally kept testing changes in reduction of the amount of power for 1 month (31 days) under the same conditions after the first test described above.

First, the average power consumption per day in May that is the period of the second test was measured as that in the following Table 8.

TABLE 8

| | |
|---|---|
| Reference | |
| meter-reading date | Power (KW) |

| | | |
|---|---|---|
| 4 PM, May 1, 2010 | 1,977,276 | |
| 4 PM, June 1, 2010 | 2,070,348 | |
| Average power | Formula: | 3,002.32 |
| consumption per day | (2,070,348 − | |
| | 1,977,276)/31(Days) | |

As shown in Table 8, the average power consumption per day was measured at 3,002.32 [KW], which means that the amount of average power consumption per day shown during the period of the first test is reduced by 190.45 [KW], which is larger than 110.37 [KW].

Further, the detail of reduction of power cost per day for 1 pyong according to the amount of money of power consumption per day is analyzed as being reduced by 256 Won, which is larger than 148 Won that was reduced during the period of the first test.

When the reduction is compared with the reduction during the period of the first test described above, it was found that the results shown in the following Tables 9 and 10 are calculated. Table 9 shows the expected amount of money that is reduced when the wind direction adjuster is applied to the headquarter of KOSCOM and A-dong and B-dong of Anyang Backup Center and Table 10 shows the expected amount of money that is reduced when the wind direction adjuster is applied to the computer rooms in Seoul and Busan of KRX.

TABLE 9

| | | | Reduced cost (year) | |
|---|---|---|---|---|
| | | Area | For 4/16 to 5/1 | |
| Item | | (pyong) | (for 15 days) | For May (31 days) |
| the 2nd basememnt of | | 249 | 13,443,420 Won | 23,266,560 Won |
| headquarter | | | | |
| Anyang | Second | 455 | 24,579,100 Won | 42,515,200 Won |
| A-dong | floor | | | |
| | Third | 455 | 24,579,100 Won | 42,515,200 Won |
| | floor | | | |

| | | | |
|---|---|---|---|
| Anyang B-dong | 150 | 8,103,000 Won | 14,016,000 Won |
| (Backup computer | | | |
| room) | | | |
| Total | 1,159 | 70,704,620 Won | 122,312,960 Won |

TABLE 10

| | | Reduced cost (year) | |
|---|---|---|---|
| | Area | For 4/16 to 5/1 | |
| Computer room | (pyong) | (for 15 days) | For May (31 days) |
| Fourth floor of | 285 | 15,395,700 Won | 26,630,400 Won |
| extension in Seoul | | | |
| Busan (fifth | 217 | 11,722,340 Won | 20,276,480 Won |
| floor of KT IDC) | | | |
| Total | 285 | 27,118,040 Won | 46,906,880 Won |

That is, as shown in Tables 9 and 10, the expected amounts of money of power that is reduced through the test performed for 1 month are 122,312,960 Won and 46,906,880 Won, which means the economic effect is larger and more remarkable.

What is claimed is:

1. A wind direction adjuster for controlling cooling air in a data center, comprising;
an access floor-flat plate; a first support, a second support, a third support, and a fourth support that form frames supporting the access floor-flat plate from below; and
a wind direction-adjusting plate for concentrating a wind direction of cooling air supplied from an air conditioner by blocking an open space between at least any two supports of the first to fourth supports in accordance with a structure of a building, an installation environment of a computing equipment, and a reach distance of the cooling air.

2. The wind direction adjuster of claim 1, wherein the wind direction-adjusting plate is fixed to any two supports of the first to fourth supports by fixing devices and is adapted to adjust a wind direction and is attachable/detachable by Velcro tapes that are easily attachable/detachable, and the wind direction adjuster further includes first to fourth bottom support members that fix and support the first to fourth supports to a floor.

3. The wind direction adjuster of claim 2, wherein the access floor-flat plate is a flat plate or a flat plate with holes.

4. A wind direction-variable type of wind direction adjuster for controlling cooling air in a data center, comprising:
an access floor-flat plate; a wind direction variator that is installed at the center on the underside of the access floor-flat plate to adjust a wind direction to be variable;
a wind direction-adjusting plate that is installed on the underside of the wind direction variator and is adapted to adjust the wind direction by integrally rotating;
a first support that is a support bar supporting the wind direction-adjusting plate to a floor; and
a first support member that allows the bottom of the first support to be seated and fixed to the floor.

5. The wind direction adjuster of claim 4, wherein the wind direction-adjusting plate and the wind direction variator are directly connected, with the access floor-flat plate therebetween, and the direction of the wind direction-adjusting plate is changed by rotating the wind direction variator to left or right.
